(19) United States
(12) Patent Application Publication
(10) Pub. No.: US 2014/0322924 A1
(43) Pub. Date: Oct. 30, 2014

(54) SILICON CONTAINING COMPOUNDS FOR ALD DEPOSITION OF METAL SILICATE FILMS

(71) Applicants: L'Air Liquide, Société Anonyme pour l'Etude et l'Exploitation des Procédés Georges Claude, Paris (FR); American Air Liquide, Inc., Fremont, CA (US); Air Liquide Electronics U.S. LP, Dallas, TX (US)

(72) Inventors: Christian DUSSARRAT, Tokyo (JP); Glenn KUCHENBEISER, Newark, DE (US); Vincent M. OMARJEE, Menlo Park, CA (US); Ziyun WANG, Allen, TX (US)

(21) Appl. No.: 14/329,108

(22) Filed: Jul. 11, 2014

Related U.S. Application Data
(63) Continuation of application No. PCT/US2012/072051, filed on Dec. 28, 2012.
(60) Provisional application No. 61/588,619, filed on Jan. 19, 2012.

(51) Int. Cl. H01L 21/02

(52) U.S. Cl. CPC H01L 21/02148; H01L 21/02208; H01L 21/0228
USPC 438/785; 106/286.4

(57) ABSTRACT

Disclosed are silicon containing compounds and their use in vapor deposition methods of hafnium silicate films having a desired silicon concentration. More particularly, deposition of hafnium silicate films by atomic layer deposition using moisture and the disclosed silicon containing compounds produce films having a desired silicon concentration.

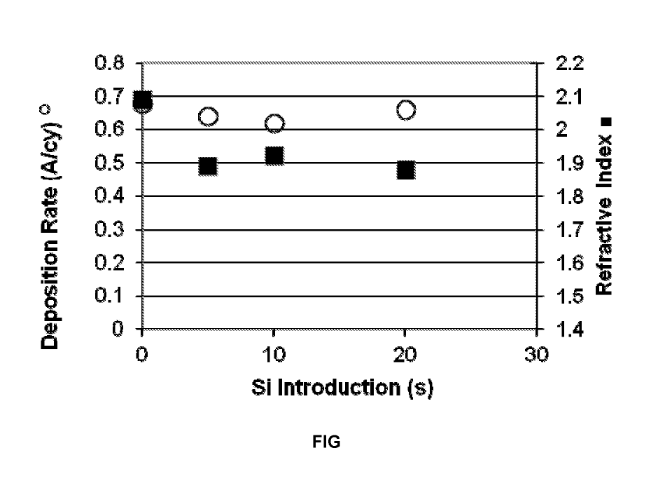

### CROSS-REFERENCE TO RELATED APPLICATIONS

This application is a continuation of International PCT Application PCT/US/2012072051, filed Dec. 8, 2012, which claims priority to U.S. provisional application No. 61/588,619, filed Jan. 19, 2012, the entire contents of each being incorporated herein by reference.

### TECHNICAL FIELD

Disclosed are silicon containing compounds and their use in vapor deposition methods of metal silicate films having a desired silicon concentration. More particularly, deposition of hafnium silicate films by atomic layer deposition using moisture and the disclosed silicon containing compounds produce films having a desired silicon concentration.

### BACKGROUND

One of the challenges the semiconductor industry faces is developing new gate dielectric materials for DRAM and capacitors. For decades, silicon dioxide (SiO₂) has been a reliable dielectric, but as transistor size continues to shrink and as technology moves from “Full Si” transistor to “Metal GateHigh-k” transistors, the reliability and capability of the SiO₂-based gate dielectric is reaching its physical limits. One solution is to use other materials, such as hafnium-based metal oxides and namely hafnium silicates, for gate dielectrics. It is in this context that these high-k materials (so-called because of their high dielectric constant) can be made much thicker than SiO₂ while achieving the same gate capacitance. High-k materials may also be used as an interlayer insulating film or spacer film.

One method of forming gate dielectrics, interlayer insulating films, and spacer films is ALD (Atomic Layer Deposition), which has been identified as an important thin film growth technique for microelectronics manufacturing. ALD relies on sequential and saturating surface reactions of alternatively applied precursors, separated by inert gas purging. The surface-controlled nature of ALD enables the growth of thin films of high conformality and uniformity with an accurate thickness control.

HfO₂ may be easily deposited by ALD using various reactants such as ozone, oxygen, or moisture. However ALD deposition of HfO₂ with ozone results in oxidation on the substrate during the ozone pulse (the ‘interface layer’), which dramatically affects the electrical properties of the resulting film. Many attempts have been made to suppress the oxidation of the silicon substrates. One such attempt has been to use moisture instead of ozone in the ALD process. However, the use of moisture for ALD deposition of silicon containing films has proven to be challenging. Additionally, deposition of hafnium silicate films having low silicon concentration has also proven challenging. See, e.g., WO2011/031591 to Wajda and Besancon et al., Abstract #1546, 218^{th} ECS Meeting of the Electrochemical Society 2010.

A need remains to be able to control the amount of silicon in hafnium silicate films deposited by ALD using moisture.

### Notation and Nomenclature

Certain abbreviations, symbols, and terms are used throughout the following description and claims and include:

The standard abbreviations of the elements from the periodic table of elements are used herein. It should be understood that elements may be referred to by these abbreviations (e.g., Si refers to silicon, Hf refers to hafnium, Zr refers to zirconium, Pd refers to palladium, Co refers to cobalt, etc).

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula HₓSi(NR₂)₄₋ₓ, where x is 2 or 3, the two or three R groups may, but need not be identical to each other. Further, it should be understood that unless specifically stated otherwise, values of R groups are independent of each other when used in different formulas.

As used herein, the term “alkyl group” refers to saturated functional groups containing exclusively carbon and hydrogen atoms, which may be linear, branched, or cyclic. Examples of linear alkyl groups include without limitation, methyl groups, ethyl groups, propyl groups, butyl groups, etc. Examples of branched alkyl groups include without limitation, isopropyl and t-butyl. Examples of cyclic alkyl groups include without limitation, cyclopropyl groups, cyclopentyl groups, cyclohexyl groups, etc. As used herein, the abbreviation “Me” refers to a methyl group; the abbreviation “Et” refers to an ethyl group; the abbreviation “Pr” refers to a generic propyl group; the abbreviation “nPr” refers to a n-propyl group; the abbreviation “iPr” refers to an isopropyl group; the abbreviation “Bu” generically refers to butyl group; the abbreviation “nBu” refers to a n-butyl group; the abbreviation “iBu” refers to an isobutyl group; the abbreviation “tBu” refers to tert-butyl; the abbreviation “sBu” refers to sec-butyl; the abbreviation “Am” generically refers to amyl (amyl=pentyl); the abbreviation “nAm” refers to n-amyl; the abbreviation “iAm” refers to isoamyl; the abbreviation “tAm” refers to tertiary amyl (also known as tert-amyl or neopentyl); the abbreviation Cp refers to cyclopentadienyl; and the abbreviation “morph” or “morpholino” refers to the cyclic structure:

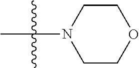 [SMILES: *N1CCOCC1]

### SUMMARY OF THE INVENTION

Disclosed are silicon containing compounds having the formula HₓSi(NR¹R²)₄₋ₓ, wherein x=1 or 2; R¹ is selected from the group consisting of isobutyl, nbutyl, secbutyl, and tertiary-amyl; and R² is H or a C1-C6 alkyl group. The disclosed silicon containing compounds may have one or more of the following aspects:

x=1;

x=2;

R¹ and R² being isobutyl;

R¹ and R² being nbutyl;

R¹ being isobutyl;

R¹ being secbutyl;

R¹ being nbutyl; and

R² being selected from the group consisting of Me, Et, iPr, and nPr.

Also disclosed are silicon containing compounds having the formula HₓSi(morpholino)₄₋ₓ, wherein x=2 or 3.

Also disclosed are silicon containing compounds having the formula H_{4-x-y}Si(morpholino)ₓ(NR¹R²)_{y}, wherein x=1, 2, 3; y=1, 2, 3; x+y≦4; and R¹ and R² are independently H or a C1-C6 alkyl group. The disclosed silicon containing compounds may have one or more of the following aspects:

x=1 and y=1;

x=1 and y=2;

x=1 and y=3

x=2 and y=1;

X=2 and y=2;

x=3 and y=1;

R¹ and R² being isobutyl;

R¹ and R² being nbutyl;

R¹ being isobutyl;

R¹ being secbutyl;

R¹ being nbutyl;

R² being selected from the group consisting of Me, Et, iPr, and nPr; and

R¹ and R² being selected from the group consisting of Me, Et, iPr, and nPr.

Also disclosed are atomic layer deposition (ALD) methods to provide a hafnium silicate film having a desired silicon concentration. A hafnium containing precursor is introduced into a chamber containing one or more substrates. At least part of the hafnium containing precursor is adsorbed on the one or more substrates to produce an adsorbed hafnium containing layer. A silicon containing precursor is selected to provide a desired concentration of silicon in the hafnium silicate film. The selected silicon containing precursor is introduced into the chamber to react with the adsorbed hafnium containing layer to provide the hafnium silicate film having the desired silicon concentration. The silicon containing precursor may be any of the silicon containing precursors disclosed above. The disclosed methods may include one or more of the following aspects:
introducing a reactant into the chamber after the chemisorption of at least part of the hafnium containing precursor;
introducing a reactant into the chamber after introducing the selected silicon containing precursor;
introducing a reactant into the chamber after the chemisorption of at least part of the hafnium containing precursor and after introducing the selected silicon containing precursor;
the reactant being H₂O;
increasing a ratio of hafnium containing precursor to silicon containing precursor to further decrease the silicon concentration;
annealing the hafnium silicate film;
the silicon containing precursor selected being bis(diisobutylamino)silane and the desired silicon concentration being between approximately 7 atomic % and approximately 50 atomic %;
the silicon containing precursor selected being bis(di-n-butylamino)silane and the desired silicon concentration being between approximately 18 atomic % and approximately 44 atomic %;
the silicon containing precursor selected being bis(diethylamino)silane and the desired silicon concentration being between approximately 39 atomic and approximately 56 atomic %;
the silicon containing precursor selected being bis(diisopropylamino)silane and the desired silicon concentration being between approximately 21 atomic % and approximately 57 atomic %; and
the silicon containing precursor selected being bis(isopropyltertbutylamino)silane and the desired silicon concentration being between approximately 15 atomic % and approximately 40 atomic %.

Also disclosed are methods of decreasing a silicon concentration in a hafnium silicate film by increasing a carbon chain length in a silicon containing compound having the formula HₓSi(NR¹R²)₄₋ₓ, wherein x is 1 or 2 and R¹ and R² are independently selected from the group consisting of H, Me, Et, nPr, iPr, nBu, iBu, tBu, sBu, and tAm. The disclosed methods may have one or more of the following aspects:
introducing a reactant into a chamber after chemisorption of at least part of a hafnium containing precursor;
introducing a reactant into a chamber after introducing the silicon containing compound;
introducing a reactant into a chamber after chemisorption of at least part of a hafnium containing precursor and after introducing the selected silicon containing compound;
the reactant being H₂O;
increasing a ratio of hafnium containing precursor to silicon containing compound to further decrease the silicon concentration;
the silicon containing compound selected being bis(diisobutylamino)silane and a desired silicon concentration being between approximately 7 atomic % and approximately 50 atomic %;
the silicon containing compound selected being bis(di-n-butylamino)silane and a desired silicon concentration being between approximately 18 atomic % and approximately 44 atomic %;
the silicon containing compound selected being bis(diethylamino)silane and a desired silicon concentration being between approximately 39 atomic and approximately 56 atomic %;
the silicon containing compound selected being bis(diisopropylamino)silane and a desired silicon concentration being between approximately 21 atomic % and approximately 57 atomic %; and
the silicon containing compound selected being bis(isopropyltertbutylamino)silane and a desired silicon concentration being between approximately 15 atomic % and approximately 40 atomic %.

### BRIEF DESCRIPTION OF THE DRAWINGS

For a further understanding of the nature and objects of the present invention, reference should be made to the following detailed description, taken in conjunction with the accompanying graphs, and wherein:

FIG is a graph showing the deposition rate and refractive index of the hafnium silicate film versus bis(diisobutylamino)silane pulse time.

### DETAILED DESCRIPTION OF PREFERRED EMBODIMENTS

Disclosed are silicon containing compounds, methods of synthesizing the same, and methods of using the same.

The disclosed silicon containing compounds have the formula HₓSi(NR¹R²)₄₋ₓ, wherein x=1 or 2; R¹ is selected from the group consisting of isobutyl, nbutyl, secbutyl, and tertiary-amyl; and R² is H or a C1-C6 alkyl group. The C1-C6 alkyl group includes any linear, branched, or cyclic alkyl groups having from 1 to 6 carbon atoms, including but not limited to Me, tBu, or cyclohexyl groups. In one alternative, x is preferably 2. In another alternative, x is preferably 1. R² is preferably Me, Et, iPr, nPr.

Also disclosed are silicon containing compounds having the formula HₓSi(morpholino)₄₋ₓ, wherein x=2 or 3.

Also disclosed are silicon containing compounds having the formula H_{4-x-y}Si(morpholino)ₓ(NR¹R²)_{y}, wherein x=1, 2, 3; y=1, 2, 3; x+y≦4; and R¹ and R² are independently H or a C1-C6 alkyl group.

The disclosed silicon containing compounds were selected to provide a metal silicon film in an atomic layer deposition process using H₂O as a reactant.

The metal may be Ti, Zr, or Hf. The disclosed silicon containing precursors contain long alkyl chains having 4 carbons or more. The long alkyl chains hinder chemisorption and therefore reduce the silicon content in the resulting silicon containing films.

Exemplary silicon containing compounds include

HSi(NⁱBu₂)₃, HSi(NⁿBu₂)₃, HSi(N^{sec}Bu₂)₃, HSi(N^{t}Am₂)₃, HSi(NⁿAm₂)₃, HSi(NⁿHexyl₂)₃, HSi(NHⁱBu)₃, HSi(NHⁿBu)₃, HSi(NH^{sec}Bu)₃, HSi(NH^{t}Am)₃, HSi(NHⁿAm)₃, HSi(NHⁿHexyl)₃, HSi(NMeⁱBu)₃, HSi(NMeⁿBu)₃, HSi(NMe^{sec}Bu)₃, HSi(NMe^{t}Am)₃, HSi(NMeⁿAm)₃, HSi(NMeⁿHexyl₂)₃,
HSi(NEtⁱBu)₃, HSi(NEtⁿBu)₃, HSi(NEt^{sec}Bu)₃, HSi(NEt^{t}Am)₃, HSi(NEtⁿAm)₃, HSi(NEtⁿHexyl₂)₃, HSi(NiPrⁱBu)₃, HSi(NiPrⁿBu)₃, HSi(NiPr^{sec}Bu)₃, HSi(NiPr^{t}Am)₃, HSi(NiPrⁿAm)₃, HSi(NiPrⁿHexyl₂)₃, HSi(NⁿPrⁱBu)₃, HSi(NⁿPrⁿBu)₃, HSi(NⁿPr^{sec}Bu)₃, HSi(NⁿPr^{t}Am)₃, HSi(NⁿPrⁿAm)₃, HSi(NⁿPrⁿHexyl₂)₃, HSi(NⁱBuⁱBu)₃, HSi(NⁱBuⁿBu)₃, HSi(NⁱBu^{sec}Bu)₃, HSi(NⁱBu^{t}Am)₃, HSi(NⁱBuⁿAm)₃, HSi(NⁱBuⁿHexyl₂)₃, HSi(NⁿBuⁱBu)₃, HSi(NⁿBuⁿBu)₃, HSi(NⁿBu^{sec}Bu)₃, HSi(NⁿBu^{t}Am)₃, HSi(NⁿBuⁿAm)₃, HSi(NⁿBuⁿHexyl₂)₃, HSi(N^{sec}BuⁱBu)₃, HSi(N^{sec}BuⁿBu)₃, HSi(N^{sec}Bu^{sec}Bu)₃, HSi(N^{sec}Bu^{t}Am)₃, HSi(N^{sec}BuⁿAm)₃, HSi(N^{sec}BuⁿHexyl₂)₃,
HSi(N^{t}BuⁱBu)₃, HSi(N^{t}BuⁿBu)₃, HSi(N^{t}Bu^{sec}Bu)₃, HSi(N^{t}Bu^{t}Am)₃, HSi(N^{t}BuⁿAm)₃, HSi(N^{t}BuⁿHexyl₂)₃, HSi(NⁿAmⁱBu)₃, HSi(NⁿAmⁿBu)₃, HSi(N^{t}BuⁿAm)₃, HSi(NⁿAm^{t}Am)₃, HSi(NⁿAmⁿAm)₃, HSi(NⁿAmⁿHexyl₂)₃, HSi(NⁱAmⁱBu)₃, HSi(NⁱAmⁿBu)₃, HSi(NⁱAm^{sec}Bu)₃, HSi(NⁱAm^{t}Am)₃, HSi(NⁱAmⁿAm)₃,
HSi(NⁱAmⁿHexyl₂)₃, HSi(N^{t}AmⁱBu)₃, HSi(N^{t}AmⁿBu)₃, HSi(N^{t}Am^{sec}Bu)₃, HSi(N^{t}Am^{t}Am)₃, HSi(N^{t}AmⁿAm)₃, HSi(N^{t}AmⁿHexyl₂)₃,
HSi(NⁿHexylⁱBu)₃, HSi(NⁿHexylⁿBu)₃, HSi(NⁿHexyl^{sec}Bu)₃, Si(NⁿHexyl^{t}Am)₃, HSi(NⁿHexylⁿAm)₃, HSi(NⁿHexylⁿHexyl₂)₃,
HSi(NⁿBu₂)₂(NⁱBu₂), HSi(N^{sec}Bu₂)₂(NⁱBu₂), HSi(N^{t}Am₂)₂(NⁱBu₂), HSi(NⁿAm₂)₂(NⁱBu₂), HSi(NⁿHexyl₂)₂(NⁱBu₂), HSi(NHⁱBu)₂(NⁱBu₂), HSi(NHⁿBu)₂(NⁱBu₂), HSi(NH^{sec}Bu)₂(NⁱBu₂), HSi(NH^{t}Am)₂(NⁱBu₂), HSi(NHⁿAm)₂(NⁱBu₂), HSi(NHⁿHexyl)₂(NⁱBu₂), HSi(NMeⁱBu)₂(NⁱBu₂), HSi(NMeⁿBu)₂(NⁱBu₂), HSi(NMe^{sec}Bu)₂(NⁱBu₂), HSi(NMe^{t}Am)₂(NⁱBu₂), HSi(NMeⁿAm)₂(NⁱBu₂), HSi(NMeⁿHexyl₂)₂(NⁱBu₂),
HSi(NEtⁱBu)₂(NⁱBu₂), HSi(NEtⁿBu)₂(NⁱBu₂), HSi(NEt^{sec}Bu)₂(NⁱBu₂), HSi(NEt^{t}Am)₂(NⁱBu₂), HSi(NEtⁿAm)₂(NⁱBu₂), HSi(NEtⁿHexyl₂)₂(NⁱBu₂), HSi(NiPrⁱBu)₂(NⁱBu₂), HSi(NiPrⁿBu)₂(NⁱBu₂), HSi(NiPr^{sec}Bu)₂(NⁱBu₂), HSi(NiPr^{t}Am)₂(NⁱBu₂), HSi(NiPrⁿAm)₂(NⁱBu₂), HSi(NiPrⁿHexyl₂)₂(NⁱBu₂), HSi(NⁿPrⁱBu)₂(NⁱBu₂), HSi(NⁿPrⁿBu)₂(NⁱBu₂), HSi(NⁿPr^{sec}Bu)₂(NⁱBu₂), HSi(NⁿPr^{t}Am)₂(NⁱBu₂), HSi(NⁿPrⁿAm)₂(NⁱBu₂), HSi(NⁿPrⁿHexyl₂)₂(NⁱBu₂), HSi(NⁱBuⁱBu)₂(NⁱBu₂), HSi(NⁱBuⁿBu)₂(NⁱBu₂), HSi(NⁱBu^{sec}Bu)₂(NⁱBu₂), HSi(NⁱBu^{t}Am)₂(NⁱBu₂), HSi(NⁱBuⁿAm)₂(NⁱBu₂), HSi(NⁱBuⁿHexyl₂)₂(NⁱBu₂), HSi(NⁿBuⁱBu)₂(NⁱBu₂), HSi(NⁿBuⁿBu)₂(NⁱBu₂), HSi(NⁿBu^{sec}Bu)₂(NⁱBu₂), HSi(NⁿBu^{t}Am)₂(NⁱBu₂), HSi(NⁿBuⁿAm)₂(NⁱBu₂), HSi(NⁿBuⁿHexyl₂)₂(NⁱBu₂), HSi(N^{sec}BuⁱBu)₂(NⁱBu₂), HSi(N^{sec}BuⁿBu)₂(NⁱBu₂), HSi(N^{sec}Bu^{sec}Bu)₂(NⁱBu₂), HSi(N^{sec}Bu^{t}Am)₂(NⁱBu₂), HSi(N^{sec}BuⁿAm)₂(NⁱBu₂), HSi(N^{sec}BuⁿHexyl₂)₂(NⁱBu₂), HSi(N^{t}BuⁱBu)₂(NⁱBu₂), HSi(N^{t}BuⁿBu)₂(NⁱBu₂), HSi(N^{t}Bu^{sec}Bu)₂(NⁱBu₂), HSi(N^{t}Bu^{t}Am)₂(NⁱBu₂), HSi(N^{t}BuⁿAm)₂(NⁱBu₂), HSi(N^{t}BuⁿHexyl₂)₂(NⁱBu₂), HSi(NⁿAmⁱBu)₂(NⁱBu₂), HSi(NⁿAmⁿBu)₂(NⁱBu₂), HSi(NⁿAm^{sec}Bu)₂(NⁱBu₂), HSi(NⁿAm^{t}Am)₂(NⁱBu₂), HSi(NⁿAmⁿAm)₂(NⁱBu₂), HSi(NⁿAmⁿHexyl₂)₂(NⁱBu₂), HSi(NⁱAmⁱBu)₂(NⁱBu₂), HSi(NⁿAmⁿBu)₂(NⁱBu₂), HSi(NⁿAm^{sec}Bu₂)₂(NⁱBu₂), HSi(NⁱAm^{t}Am)₂(NⁱBu₂), HSi(NⁱAmⁿAm)₂(NⁱBu₂), HSi(NⁱAmⁿHexyl₂)₂(NⁱBu₂), HSi(N^{t}AmⁱBu)₂(NⁱBu₂), HSi(N^{t}AmⁿBu)₂(NⁱBu₂), HSi(N^{t}Am^{sec}Bu)₂(NⁱBu₂), HSi(N^{t}Am^{t}Am)₂(NⁱBu₂), HSi(N^{t}AmⁿAm)₂(NⁱBu₂), HSi(N^{t}AmⁿHexyl₂)₂(NⁱBu₂), HSi(NⁿHexylⁱBu)₂(NⁱBu₂), HSi(NⁿHexylⁿBu)₂(NⁱBu₂), HSi(NⁿHexyl^{sec}Bu)₂(NⁱBu₂), Si(NⁿHexyl^{t}Am)₂(NⁱBu₂), HSi(NⁿHexylⁿAm)₂(NⁱBu₂), HSi(NⁿHexylⁿHexyl)₂(NⁱBu₂),
H₂Si(NⁱBu₂)₂, H₂Si(NⁿBu₂)₂, H₂Si(N^{sec}Bu₂)₂, H₂Si(N^{t}Am₂)₂, H₂Si(NⁿAm₂)₂, H₂Si(NⁿHexyl₂)₂, H₂Si(NHⁱBu)₂, H₂Si(NHⁿBu)₂, H₂Si(NH^{sec}Bu)₂, H₂Si(NH^{t}Am)₂, H₂Si(NHⁿAm)₂, H₂Si(NHⁿHexyl)₂, H₂Si(NMeⁱBu)₂, H₂Si(NMeⁿBu)₂, H₂Si(NMe^{sec}Bu)₂, H₂Si(NMe^{t}Am)₂, H₂Si(NMeⁿAm)₂, H₂Si(NMeⁿHexyl)₂, H₂Si(NEtⁱBu)₂, H₂Si(NEtⁿBu)₂, H₂Si(NEt^{sec}Bu)₂, H₂Si(NEt^{t}Am)₂, H₂Si(NEtⁿAm)₂, H₂Si(NEtⁿHexyl)₂, H₂Si(NiPrⁱBu)₂, H₂Si(NiPrⁿBu)₂, H₂Si(NiPr^{sec}Bu)₂, H₂Si(NiPr^{t}Am)₂, H₂Si(NiPrⁿAm)₂, H₂Si(NiPrⁿHexyl)₂, H₂Si(NⁿPrⁱBu)₂, H₂Si(NⁿPrⁿBu)₂, H₂Si(NⁿPr^{sec}Bu)₂, H₂Si(NⁿPr^{t}Am)₂, H₂Si(NⁿPrⁿAm)₂, H₂Si(NⁿPrⁿHexyl)₂, H₂Si(NⁱBuⁱBu)₂, H₂Si(NⁱBuⁿBu)₂, H₂Si(NⁱBu^{sec}Bu)₂, H₂Si(NⁱBu^{t}Am)₂, H₂Si(NⁱBuⁿAm)₂, H₂Si(NⁱBuⁿHexyl)₂, H₂Si(NⁿBu)₂, H₂Si(NⁿBuⁿBu)₂, H₂Si(NⁿBu^{sec}Bu)₂, H₂Si(NⁿBu^{t}Am)₂, H₂Si(NⁿBuⁿAm)₂, H₂Si(NⁿBuⁿHexyl)₂, H₂Si(N^{sec}BuⁱBu)₂, H₂Si(N^{sec}BuⁿBu)₂, H₂Si(N^{sec}Bu^{sec}Bu)₂, H₂Si(N^{sec}Bu^{t}Am)₂, H₂Si(N^{sec}BuⁿAm)₂, H₂Si(N^{sec}BuⁿHexyl)₂, H₂Si(N^{t}BuⁱBu)₂, H₂Si(N^{t}BuⁿBu)₂, H₂Si(N^{t}Bu^{sec}Bu)₂, H₂Si(N^{t}Bu^{t}Am)₂, H₂Si(N^{t}BuⁿAm)₂, H₂Si(N^{t}BuⁿHexyl)₂, H₂Si(NⁿAmⁱBu)₂, H₂Si(NⁿAmⁿBu)₂, H₂Si(NⁿAm^{sec}Bu)₂, H₂Si(NⁿAm^{t}Am)₂, H₂Si(NⁿAmⁿAm)₂, H₂Si(NⁿAmⁿHexyl)₂, H₂Si(NⁱAmⁱBu)₂, H₂Si(NⁱAmⁿBu)₂, H₂Si(NⁱAm^{sec}Bu)₂, H₂Si(NⁱAm^{t}Am)₂, H₂Si(NⁱAmⁿAm)₂, H₂Si(NⁱAmⁿHexyl)₂, H₂Si(N^{t}AmⁱBu)₂, H₂Si(N^{t}AmⁿBu)₂, H₂Si(N^{t}Am^{sec}Bu)₂, H₂Si(N^{t}Am^{t}Am)₂, H₂Si(N^{t}AmⁿAm)₂, H₂Si(N^{t}AmⁿHexyl)₂, H₂Si(NⁿHexylⁱBu)₂, H₂Si(NⁿHexylⁿBu)₂, H₂Si(NⁿHexyl^{sec}Bu)₂, H₂Si(NⁿHexyl^{t}Am)₂, H₂Si(NⁿHexylⁿAm)₂, H₂Si(NⁿHexylⁿHexyl)₂,
H₂Si(NⁱBu₂)(NⁱBuⁱPr), H₂Si(NⁿBu₂)(NⁱBuⁱPr), H₂Si(N^{sec}Bu₂)(NⁱBuⁱPr), H₂Si(N^{t}Am₂)(NⁱBuⁱPr), H₂Si(NⁿAm₂)(NⁱBuⁱPr), H₂Si(NⁿHexyl₂)(NⁱBuⁱPr), H₂Si(NHⁱBu)(NⁱBuⁱPr), H₂Si(NHⁿBu)(NⁱBuⁱPr), H₂Si(NH^{sec}Bu)(NⁱBuⁱPr), H₂Si(NH^{t}Am)(NⁱBuⁱPr), H₂Si(NHⁿAm)(NⁱBuⁱPr), H₂Si(NHⁿHexyl)(NⁱBuⁱPr), H₂Si(NMeⁱBu)(NⁱBuⁱPr), H₂Si(NMeⁿBu)(NⁱBuⁱPr), H₂Si(NMe^{sec}Bu)(NⁱBuⁱPr), H₂Si(NMe^{t}Am)(NⁱBuⁱPr), H₂Si(NMeⁿAm)(NⁱBuⁱPr), H₂Si(NMeⁿHexyl)(NⁱBuⁱPr), H₂Si(NEtⁱBu)(NⁱBuⁱPr), H₂Si(NEtⁿBu)(NⁱBuⁱPr), H₂Si(NEt^{sec}Bu)(NⁱBuⁱPr), H₂Si(NEt^{t}Am)(NⁱBuⁱPr), H₂Si(NEtⁿAm)(NⁱBuⁱPr), H₂Si(NEtⁿHexyl)(NⁱBuⁱPr), H₂Si(NiPrⁱBu)(NⁱBuⁱPr), H₂Si(NiPrⁿBu)(NⁱBuⁱPr), H₂Si(NiPr^{sec}Bu)(NⁱBuⁱPr), H₂Si(NiPr^{t}Am)(NⁱBuⁱPr), H₂Si(NiPrⁿAm)(NⁱBuⁱPr), H₂Si(NiPrⁿHexyl)(NⁱBuⁱPr), H₂Si(NⁿPr^{t}Am)(NⁱBuⁱPr), H₂Si(NⁿPrⁿBu)(NⁱBuⁱPr), H₂Si(NⁿPr^{sec}Bu)(NⁱBuⁱPr), H₂Si(NⁿPr^{t}Am)(NⁱBuⁱPr), H₂Si(NⁿPrⁿAm)(NⁱBuⁱPr), H₂Si(NⁿPrⁿHexyl)(NⁱBuⁱPr), H₂Si(NⁱBuⁱBu)(NⁱBuⁱPr), H₂Si(NⁱBuⁿBu)(NⁱBuⁱPr), H₂Si(NⁱBu^{sec}Bu)(NⁱBuⁱPr), H₂Si(NⁱBu^{t}Am)(NⁱBuⁱPr), H₂Si(NⁱBuⁿAm)(NⁱBuⁱPr), H₂Si(NⁱBuⁿHexyl)(NⁱBuⁱPr), H₂Si(NⁿBuⁱBu)(NⁱBuⁱPr), H₂Si(NⁿBuⁿBu)(NⁱBuⁱPr), H₂Si(NⁿBu^{sec}Bu)(NⁱBuⁱPr), H₂Si(NⁿBu^{t}Am)(NⁱBuⁱPr), H₂Si(NⁿBuⁿAm)(NⁱBuⁱPr), H₂Si(NⁿBuⁿHexyl)(NⁱBuⁱPr), H₂Si(N^{sec}BuⁱBu)(NⁱBuⁱPr), H₂Si(N^{sec}BuⁿBu)(NⁱBuⁱPr), H₂Si(N^{sec}Bu^{sec}Bu)(NⁱBuⁱPr), H₂Si(N^{sec}Bu^{t}Am)(NⁱBuⁱPr), H₂Si(N^{sec}BuⁿAm)(NⁱBuⁱPr), H₂Si(N^{sec}BuⁿHexyl)(NⁱBuⁱPr), H₂Si(N^{t}BuⁱBu)(NⁱBuⁱPr), H₂Si(N^{t}BuⁿBu)(NⁱBuⁱPr), H₂Si(N^{t}Bu^{sec}Bu)(NⁱBuⁱPr), H₂Si(N^{t}Bu^{t}Am)(NⁱBuⁱPr), H₂Si(N^{t}BuⁿAm)(NⁱBuⁱPr), H₂Si(N^{t}BuⁿHexyl)(NⁱBuⁱPr), H₂Si(NⁿAmⁱBu)(NⁱBuⁱPr), H₂Si(NⁿAmⁿBu)(NⁱBuⁱPr), H₂Si(NⁿAm^{sec}Bu)(NⁱBuⁱPr), H₂Si(NⁿAm^{t}Am)(NⁱBuⁱPr), H₂Si(NⁿAmⁿAm)(NⁱBuⁱPr), H₂Si(NⁿAmⁿHexyl)(NⁱBuⁱPr), H₂Si(NⁱAmⁱBu)(NⁱBuⁱPr), H₂Si(NⁱAmⁿBu)(NⁱBuⁱPr), H₂Si(NⁱAm^{sec}Bu)(NⁱBuⁱPr), H₂Si(NⁱAm^{t}Am)(NⁱBuⁱPr), H₂Si(NⁱAmⁿAm)(NⁱBuⁱPr), H₂Si(NⁱAmⁿHexyl)(NⁱBuⁱPr), H₂Si(N^{t}AmⁱBu)(NⁱBuⁱPr), H₂Si(N^{t}AmⁿBu)(NⁱBuⁱPr), H₂Si(N^{t}Am^{sec}Bu)(NⁱBuⁱPr), H₂Si(N^{t}Am^{t}Am)(NⁱBuⁱPr), H₂Si(N^{t}AmⁿAm)(NⁱBuⁱPr), H₂Si(N^{t}AmⁿHexyl)(NⁱBuⁱPr), H₂Si(NⁿHexylⁱBu)(NⁱBuⁱPr), H₂Si(NⁿHexylⁿBu)(NⁱBuⁱPr), H₂Si(NⁿHexyl^{sec}Bu)(NⁱBuⁱPr), H₂Si(NⁿHexyl^{t}Am)(NⁱBuⁱPr), H₂Si(NⁿHexylⁿAm)(NⁱBuⁱPr), H₂Si(NⁿHexylⁿHexyl)(NⁱBuⁱPr),
HSi(morph)(N Bu₂)₂, HSi(morph)(NⁿBu₂)₂, HSi(morph)(N^{sec}Bu₂)₂, HSi(morph)(N^{t}Am₂)₂, HSi(morph)(NⁿAm₂)₂, HSi(morph)(NⁿHexyl₂)₂, HSi(morph)(NHⁱBu)₂, HSi(morph)(NHⁿBu)₂, HSi(morph)(NH^{sec}Bu)₂, HSi(morph)(NH^{t}Am)₂, HSi(morph)(NHⁿAm)₂, HSi(morph)(NHⁿHexyl)₂, HSi(morph)(NMeⁱBu)₂, HSi(morph)(NMeⁿBu)₂, HSi(morph)(NMe^{sec}Bu)₂, HSi(morph)(NMe^{t}Am)₂, HSi(morph)(NMeⁿAm)₂, HSi(morph)(NMeⁿHexyl)₂, HSi(morph)(NEtⁱBu)₂, HSi(morph)(NEtⁿBu)₂, HSi(morph)(NEt^{sec}Bu)₂, HSi(morph)(NEt^{t}Am)₂, HSi(morph)(NEtⁿAm)₂, HSi(morph)(NEtⁿHexyl)₂, HSi(morph)(NiPrⁱBu)₂, HSi(morph)(NiPrⁿBu)₂, HSi(morph)(NiPr^{sec}Bu)₂, HSi(morph)(NiPr^{t}Am)₂, HSi(morph)(NiPrⁿAm)₂, HSi(morph)(NiPrⁿHexyl)₂, HSi(morph)(NⁿPrⁱBu)₂, HSi(morph)(NⁿPrⁿBu)₂, HSi(morph)(NⁿPr^{sec}Bu)₂, HSi(morph)(NⁿPr^{t}Am)₂, HSi(morph)(NⁿPrⁿAm)₂, HSi(morph)(NⁿPrⁿHexyl)₂, HSi(morph)(NⁱBuⁱBu)₂, HSi(morph)(NⁱBuⁿBu)₂, HSi(morph)(NⁱBu^{sec}Bu)₂, HSi(morph)(NⁱBu^{t}Am)₂, HSi(morph)(NⁿBuⁿAm)₂, HSi(morph)(NⁿBuⁿHexyl)₂, HSi(morph)(NⁿBuⁱBu)₂, HSi(morph)(NⁿBuⁿBu)₂, HSi(morph)(NⁿBu^{sec}Bu)₂, HSi(morph)(NⁿBu^{t}Am)₂, HSi(morph)(NⁿBuⁿAm)₂, HSi(morph)(NⁿBuⁿHexyl)₂, HSi(morph)(N^{sec}BuⁱBu)₂, HSi(morph)(N^{sec}BuⁿBu)₂, HSi(morph)(N^{sec}Bu^{sec}Bu)₂, HSi(morph)(N^{sec}Bu^{t}Am)₂, HSi(morph)(N^{sec}BuⁿAm)₂, HSi(morph)(N^{sec}BuⁿHexyl)₂, HSi(morph)(N^{t}BuⁱBu)₂, HSi(morph)(N^{t}BuⁿBu)₂, HSi(morph)(N^{t}Bu^{sec}Bu)₂, HSi(morph)(N^{t}Bu^{t}Am)₂, HSi(morph)(N^{t}BuⁿAm)₂, HSi(morph)(N^{t}BuⁿHexyl)₂, HSi(morph)(NⁿAmⁱBu)₂, HSi(morph)(NⁿAmⁿBu)₂, HSi(morph)(NⁿAm^{sec}Bu)₂, HSi(morph)(NⁿAm^{t}Am)₂, Si(morph)(NⁿAmⁿAm)₂, HSi(morph)(NⁿAmⁿHexyl)₂, HSi(morph)(NⁱAmⁱBu)₂, HSi(morph)(NⁱAmⁿBu)₂, HSi(morph)(NⁱAm^{sec}Bu)₂, HSi(morph)(NⁱAm^{t}Am)₂, HSi(morph)(NⁱAmⁿAm)₂, HSi(morph)(NⁱAmⁿHexyl)₂, HSi(morph)(N^{t}AmⁱBu)₂, HSi(morph)(N^{t}AmⁿBu)₂, HSi(morph)(N^{t}Am^{sec}Bu)₂, HSi(morph)(N^{t}Am^{t}Am)₂, HSi(morph)(N^{t}AmⁿAm)₂, HSi(morph)(N^{t}AmⁿHexyl)₂, HSi(morph)(NⁿHexylⁱBu)₂, HSi(morph)(NⁿHexylⁿBu)₂, HSi(morph)(NⁿHexyl^{sec}Bu)₂, Si(morph)(NⁿHexyl^{t}Am)₂, HSi(morph)(NⁿHexylⁿAm)₂, HSi(morph)(NⁿHexylⁿHexyl)₂,
HSi(morph)₂(NⁱBu₂), HSi(morph)₂(NⁿBu₂), HSi(morph)₂(N^{sec}Bu₂), HSi(morph)₂(N^{t}Am₂), HSi(morph)₂(NⁿAm₂), HSi(morph)₂(NⁿHexyl₂), HSi(morph)₂(NHⁱBu), HSi(morph)₂(NHⁿBu), HSi(morph)₂(NH^{sec}Bu), HSi(morph)₂(NH^{t}Am), HSi(morph)₂(NHⁿAm), HSi(morph)₂(NHⁿHexyl), HSi(morph)₂(NMeⁱBu), HSi(morph)₂(NMeⁿBu), HSi(morph)₂(NMe^{sec}Bu), HSi(morph)₂(NMe^{t}Am), HSi(morph)₂(NMeⁿAm), HSi(morph)₂(NMeⁿHexyl), HSi(morph)₂(NEtⁱBu), HSi(morph)₂(NEtⁿBu), HSi(morph)₂(NEt^{sec}Bu), HSi(morph)₂(NEt^{t}Am), HSi(morph)₂(NEtⁿAm), HSi(morph)₂(NEtⁿHexyl), HSi(morph)₂(NiPrⁱBu), HSi(morph)₂(NiPrⁿBu), HSi(morph)₂(NiPr^{sec}Bu), HSi(morph)₂(NiPr^{t}Am), HSi(morph)₂(NiPrⁿAm), HSi(morph)₂(NiPrⁿHexyl), HSi(morph)₂(NⁿPrⁱBu), HSi(morph)₂(NⁿPrⁿBu), HSi(morph)₂(NⁿPr^{sec}Bu), HSi(morph)₂(NⁿPr^{t}Am), HSi(morph)₂(NⁿPrⁿAm), HSi(morph)₂(NⁿPrⁿHexyl), HSi(morph)₂(NⁱBuⁱBu), HSi(morph)₂(NⁱBuⁿBu), HSi(morph)₂(NⁱBu^{sec}Bu), HSi(morph)₂(NⁱBu^{t}Am), HSi(morph)₂(NⁱBuⁿAm), HSi(morph)₂(NⁱBuⁿHexyl), HSi(morph)₂(NⁿBuⁱBu), HSi(morph)₂(NⁿBuⁿBu), HSi(morph)₂(NⁿBu^{sec}Bu), HSi(morph)₂(NⁿBu^{t}Am), HSi(morph)₂(NⁿBuⁿAm), HSi(morph)₂(NⁿBuⁿHexyl), HSi(morph)₂(N^{sec}BuⁱBu), HSi(morph)₂(N^{sec}BuⁿBu), HSi(morph)₂(N^{sec}Bu^{sec}Bu), HSi(morph)₂(N^{sec}Bu^{t}Am), HSi(morph)₂(N^{sec}BuⁿAm), and HSi(morph)₂(N^{sec}BuⁿHexyl).

When films having low silicon concentrations are desired, the silicon containing precursor is preferably H₂Si(NⁱBu₂)₂, H₂Si(NⁿBu₂)₂, or H₂Si(NⁱPr^{t}Bu₂)₂. When films having high silicon concentrations are desired, the silicon containing film is preferably H₂Si(NⁱPr₂)₂ and H₂Si(NEt₂)₂.

The disclosed precursors may be synthesized by reacting H₂SiX₂, wherein X is F, Cl, Br, or I, with 2 equivalents of LiNR₂, with R being R¹ an R² as defined above or morph, to produce H₂Si(NR₂)₂ and HSi(NR₂)₃, as shown below, or H₂Si(morph)₂ and HSi(morph)₃:

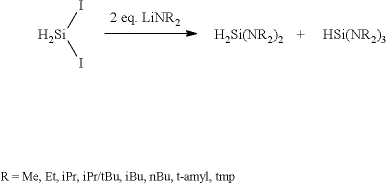

The product mixture varies depending on R group.

Alternatively, the disclosed precursors may be synthesized by reacting

H₂SiX₂, wherein X is F, Cl, Br, or I, with 2 equivalents of HNR₂, with R being R¹ an R² as defined above or morph, to produce H₂Si(NR₂)X or H₂Si(morph)X. H₂Si(NR₂)X or H₂Si(morph)X is then reacted with 2 equivalents of HNR₂ to produce H₂Si(NR₂)₂ or H₂Si(morph)₂. The reaction scheme is illustrated below with R=iPr.

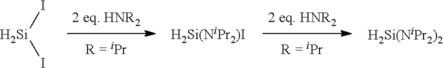

Additional synthesis details are provided in the Examples.

Also disclosed are methods of using the disclosed silicon containing compounds for vapor deposition methods. The disclosed methods provide for the use of the silicon containing compounds for deposition of silicon containing films. The disclosed methods may be useful in the manufacture of semiconductor, photovoltaic, LCD-TFT, or flat panel type devices. The methods include: providing a substrate; providing a vapor including at least one of the disclosed silicon containing compounds: and contacting the vapor with the substrate (and typically directing the vapor to the substrate) to form a silicon containing layer on at least one surface of the substrate.

The disclosed silicon containing compounds may be used to deposit silicon containing films using any deposition methods known to those of skill in the art. Examples of suitable deposition methods include without limitation, conventional chemical vapor deposition (CVD), low pressure chemical vapor deposition (LPCVD), atomic layer deposition (ALD), pulsed chemical vapor deposition (P-CVD), plasma enhanced atomic layer deposition (PE-ALD), spatial ALD, or combinations thereof. Preferably, the deposition method is ALD, spatial ALD, or PE-ALD.

The vapor of the silicon containing precursor is introduced into a reaction chamber containing at least one substrate. The temperature and the pressure within the reaction chamber and the temperature of the substrate are held at suitable conditions so that contact between the silicon containing precursor and substrate results in formation of a Si-containing layer on at least one surface of the substrate. A reactant may also be used to help in formation of the Si-containing layer.

The reaction chamber may be any enclosure or chamber of a device in which deposition methods take place, such as, without limitation, a parallel-plate type reactor, a cold-wall type reactor, a hot-wall type reactor, a single-wafer reactor, a multi-wafer reactor, or other such types of deposition systems. All of these exemplary reaction chambers are capable of serving as an ALD reaction chamber. The reaction chamber may be maintained at a pressure ranging from about 0.1 mTorr to about 100 Torr, preferably from about 0.1 Torr to about 10 Torr. In addition, the temperature within the reaction chamber may range from about 150° C. to about 400° C., preferably from about 200° C. to about 350° C. One of ordinary skill in the art will recognize that the temperature and pressure may be optimized through mere experimentation to achieve the desired result.

The temperature of the reaction chamber may be controlled by either controlling the temperature of the substrate holder or controlling the temperature of the reactor wall. Devices used to heat the substrate are known in the art. The reactor wall may be heated to a sufficient temperature to obtain the desired film at a sufficient growth rate and with desired physical state and composition. A non-limiting exemplary temperature range to which the reactor wall may be heated includes from approximately 200° C. to approximately 600° C. When a plasma deposition process is utilized, the deposition temperature may range from approximately 150° C. to approximately 350° C. Alternatively, when a thermal process is performed, the deposition temperature may range from approximately 200° C. to approximately 400° C.

Alternatively, the substrate may be heated to a sufficient temperature to obtain the desired silicon containing film at a sufficient growth rate and with desired physical state and composition. A non-limiting exemplary temperature range to which the substrate may be heated includes from 150° C. to 600° C. Preferably, the temperature of the substrate remains less than or equal to 400° C.

The type of substrate upon which the silicon containing film will be deposited will vary depending on the final use intended. In some embodiments, the substrate may be chosen from oxides which are used as dielectric materials in gate, MIM, DRAM, or FeRam technologies (for example, HfO₂ based materials, TiO₂ based materials, ZrO₂ based materials, rare earth oxide based materials, ternary oxide based materials, etc.) or from nitride-based films (for example, TaN) that are used as an oxygen barrier between copper and the low-k layer. Other substrates may be used in the manufacture of semiconductors, photovoltaics, LCD-TFT, or flat panel devices. Examples of such substrates include, but are not limited to, solid substrates such as metal nitride containing substrates (for example, TaN, TiN, WN, TaCN, TiCN, TaSiN, and TiSiN); insulators (for example, SiO₂, Si₃N₄, SiON, HfO₂, Ta₂O₅, ZrO₂, TiO₂, Al₂O₃, and barium strontium titanate); or other substrates that include any number of combinations of these materials. The actual substrate utilized may also depend upon the specific precursor embodiment utilized. In many instances, the preferred substrate utilized will be selected from Si substrates, SiGe substrates, SiGe(Sn) substrates, SiGe(C) substrates, SiC substrates, III-V substrates, such as GaAs, GaN, (Al,Ga)(As,P), and II-VI substrates such as ZnSe substrates.

The silicon containing precursor may be fed in liquid state to a vaporizer where it is vaporized before it is introduced into the reaction chamber. Prior to its vaporization, the silicon containing precursor may optionally be mixed with one or more solvents, one or more metal sources, and a mixture of one or more solvents and one or more metal sources. The solvents may be selected from the group consisting of toluene, ethyl benzene, xylene, mesitylene, decane, dodecane, octane, hexane, pentane, or others. The resulting concentration may range from approximately 0.05 M to approximately 2 M. The metal source may include any metal-containing precursors now known or later developed.

Alternatively, the silicon containing precursor may be vaporized by passing a carrier gas into a container containing the silicon containing precursor or by bubbling the carrier gas into the silicon containing precursor. The carrier gas and silicon containing precursor are then introduced into the reaction chamber as a vapor. The carrier gas may include, but is not limited to, Ar, He, N₂, and mixtures thereof. The silicon containing precursor may optionally be mixed in the container with one or more solvents, metal-containing precursors, or mixtures thereof. If necessary, the container may be heated to a temperature that permits the silicon containing precursor to be in its liquid phase and to have a sufficient vapor pressure. The container may be maintained at temperatures in the range of, for example, approximately 0° C. to approximately 150° C. Those skilled in the art recognize that the temperature of the container may be adjusted in a known manner to control the amount of silicon containing precursor vaporized.

In addition to the optional mixing of the silicon containing precursor with solvents, metal-containing precursors, and stabilizers prior to introduction into the reaction chamber, the silicon containing precursor may be mixed with reactants inside the reaction chamber. Exemplary reactants include, without limitation, metal-containing precursors such as strontium-containing precursors, barium-containing cursors, aluminum-containing precursors such as TMA, and any combination thereof. These or other metal-containing precursors may be incorporated into the resultant film in small quantities, as a dopant, or as a second or third metal in the resulting film, such as BST and STO.

A reactant may be introduced into the chamber after adsorption of the hafnium containing precursor onto the substrate, after introducing the selected silicon containing precursor, or after both. In spatial ALD, the reactant may be introduced at the same time as, but at a different location than the hafnium containing precursor and silicon containing precursor. Suitable reactants include O₂, O₃, H₂O, H₂O₂, acetic acid, formalin, para-formaldehyde, and combinations thereof. However, as discussed previously, to prevent formation of the interface layer, H₂O is preferably used as the reactant.

The reactant may be treated by plasma in order to decompose the reactant into its radical form. The plasma may be generated or present within the reaction chamber itself. Alternatively, the plasma may generally be at a location removed from the reaction chamber, for instance, in a remotely located plasma system. One of skill in the art will recognize methods and apparatus suitable for such plasma treatment.

For example, the reactant may be introduced into a direct plasma reactor, which generates a plasma in the reaction chamber, to produce the plasma-treated reactant in the reaction chamber. Exemplary direct plasma reactors include the Titan™ PECVD System produced by Trion Technologies. The reactant may be introduced and held in the reaction chamber prior to plasma processing. Alternatively, the plasma processing may occur simultaneously with the introduction of reactant. In-situ plasma is typically a 13.56 MHz RF capacitively coupled plasma that is generated between the showerhead and the substrate holder. The substrate or the showerhead may be the powered electrode depending on whether positive ion impact occurs. Typical applied powers in in-situ plasma generators are from approximately 100 W to approximately 1000 W. The disassociation of the reactant using in-situ plasma is typically less than achieved using a remote plasma source for the same power input and is therefore not as efficient in reactant disassociation as a remote plasma system, which may be beneficial for the deposition of metal-nitride-containing films on substrates easily damaged by plasma.

Alternatively, the plasma-treated reactant may be produced outside of the reaction chamber. The MKS Instruments' ASTRON®i reactive gas generator may be used to treat the reactant prior to passage into the reaction chamber. Operated at 2.45 GHz, 7 kW plasma power, and a pressure ranging from approximately 3 Torr to approximately 10 Torr, the reactant O₃ may be decomposed into three O⁻ radicals. Preferably, the remote plasma may be generated with a power ranging from about 1 kW to about 10 kW, more preferably from about 2.5 kW to about 7.5 kW.

The silicon containing precursor and one or more reactants may be introduced into the reactor simultaneously (chemical vapor deposition), sequentially (atomic layer deposition), or in other combinations. For example, the silicon containing compound may be introduced in one pulse and two additional precursors may be introduced together in a separate pulse [modified atomic layer deposition]. Alternatively, the reactor may already contain the reactant prior to introduction of the silicon containing compound. Alternatively, the silicon containing compound may be introduced to the reactor continuously while other reactants are introduced by pulse (pulsed-chemical vapor deposition). The reactant may be passed through a plasma system localized or remotely from the reactor, and decomposed to radicals. In each example, a pulse may be followed by a purge or evacuation step to remove excess amounts of the component introduced. In each example, the pulse may last for a time period ranging from about 0.01 s to about 10 s, alternatively from about 0.3 s to about 3 s, alternatively from about 0.5 s to about 2 s. In another alternative, the silicon containing compound and one or more reactants may be simultaneously sprayed from a shower head under which a susceptor holding several wafers is spun (spatial ALD).

In one embodiment, the disclosed silicon containing compounds are used in atomic layer deposition (ALD) methods to provide metal silicate films having a desired silicon concentration, and more preferably to produce hafnium silicate films. In this embodiment, a hafnium containing precursor is introduced into a chamber containing one or more substrates. At least part of the hafnium containing precursor is adsorbed on the substrates to produce an adsorbed hafnium containing layer. A silicon containing precursor is selected to provide a desired concentration of silicon in the hafnium silicate film. The selected silicon containing precursor is introduced into the chamber to react with the adsorbed hafnium containing layer to provide the hafnium silicate film having the desired silicon concentration.

As ALD of silicon oxide using moisture has been difficult, Applicants believe that the metal in the previously deposited hafnium (or titanium or zirconium) oxide layer acts as a catalyst to facilitate deposition of the ALD SiO layer. Applicants believe the hafnium (or titanium or zirconium) oxide layer enhances the absorption and the reaction of the silicon source on the surface allowing the silicate formation and therefore the hafnium (or titanium or zirconium) silicate formation.

The hafnium containing precursor may be selected from the group consisting of alkylamide hafnium precursors, such as Hf(NEtMe)₄, Hf(NMe₂)₄, or Hf(NEt₂)₄; cyclopentadienyl alkylamide hafnium precursors having the formula Hf(RₓCp)(NR₂)₃ with x being 0-5 and R being a C1-C6 alkyl group, such as HfCp(NMe₂)₃, Hf(MeCp)(NMe₂)₃, and Hf(Me₅Cp)(NMe₂)₃; Hf(EtCp₂)Me₂; (trimethylcyclohexadienyl)tris(dimethylamido)hafnium; Hf(O^{t}Bu)₄; HfCl₄; or a combination thereof. Preferably, the hafnium containing precursor is Hf(NEt₂)₄ or Hf(NEtMe)₄. The hafnium containing precursor may be supplied to the reactor in the same form as the silicon containing precursor. In other words, the hafnium containing precursor is provided in vapor form by being fed in liquid state to a vaporizer where it is vaporized, by passing a carrier gas into a container containing the hafnium containing precursor, by bubbling the carrier gas into the hafnium containing precursor, or using sublimators to vaporize solid precursors, such as the sublimator disclosed in WO2009087609, which is incorporated herein in its entirety by reference. The hafnium containing precursor may also be mixed with one or more solvents, one or more metal sources, and a mixture of one or more solvents and one or more metal sources.

The metal silicate film may be deposited on the same substrates previously listed. Preferably, the metal silicate film will be deposited on Si substrates, SiGe substrates, SiGe(Sn) substrates, SiGe(C) substrates, SiC substrates, III-V substrates, such as GaAs, GaN, (Al,Ga)(As,P), and II-VI substrates such as ZnSe substrates. The temperature and pressure conditions within the reactor are the same as previously listed.

These conditions within the reactor permit at least part of the hafnium containing precursor to adsorb on the substrates. It is believed that ALD processes result in chemisorption. However, a sharp distinction does not exist between chemisorption (chemical adsorption) and physisorption (physical adsorption) and both phenomena may occur simultaneously. Chemisorption is adsorption in which the hafnium containing precursor chemically reacts with the surface of the substrate. The adsorbed portion of the precursor is linked to the substrate by valence bonds and occupies certain adsorption sites on the surface. As a result, one layer of chemisorbed molecules is formed (which produces the self-limiting nature of ALD). Physisorption is adsorption in which the hafnium containing precursor physically reacts with the surface of the substrate. The adsorbed portion of the precursor is linked to the substrate by intermolecular forces (van der Waals forces), which do not result in a change in the electronic orbital patterns of the precursor.

The desired concentration of silicon in the hafnium silicate film is determined by the application. For example, if the hafnium silicate film will be a spacer film, the silicon concentration in the hafnium silicate film may be approximately 20 atomic % to approximately 50 atomic %, preferably from approximately 35 atomic % to approximately 45 atomic %. Alternatively, if the hafnium silicate film will be a gate dielectric, the silicon concentration in the hafnium silicate film may be approximately 5 atomic % to approximately 25 atomic %, preferably from approximately 10 atomic % to approximately 20 atomic %.

The concentration of silicon in the hafnium silicate film may be decreased by increasing the carbon chain length of the disclosed silicon containing compounds. For example, to provide metal silicate films having low silicon concentrations, the silicon containing precursor selected would be H₂Si(NⁱBu₂)₂, H₂Si(NⁿBu₂)₂, or H₂Si(NⁱPr^{t}Bu₂)₂. When metal silicate films having high silicon concentrations are desired, the silicon containing film selected would be H₂Si(NⁱPr₂)₂ and H₂Si(NEt₂)₂.

The silicon concentration of the metal silicate film may be further decreased by increasing the ratio of hafnium containing precursor to silicon containing precursor. For example, the silicon concentration in a hafnium silicate film produced from a 1:1 ratio of the hafnium containing precursor to the silicon containing precursor would be higher than the silicon concentration in a hafnium silicate film produced from a 4:1 ratio of the hafnium containing precursor to the silicon containing precursor. One of ordinary skill in the art will recognize that the ratios may be adjusted by increasing the pulse length or the number of pulses of either precursor.

Zirconium silicate and titanium silicate films may also be provided using the disclosed methods with suitable zirconium containing or titanium containing precursors. Suitable zirconium containing or titanium containing precursors include the analogs of the disclosed hafnium containing precursors. Additional suitable titanium containing precursors disclosed in US Pat App Pub No. WO2011/127122 having the formula Ti(R₁—N—C(R₃)—N—R₂)ᵤ(OR₄)ₓ(NR₅R₆)_{y}(O₂CR₇)_{z} or Ti(R₁—N—(C(R₃)₂)ₘ—N—R₂)ᵥ(OR₄)ₓ(NR₅R₆)_{y}(O₂CR₇)_{z}, wherein R₁, R₂, R₅, R₆, and R₇ are independently selected from the group consisting of H and C1-C6 alkyl group; R₃═H, C1-C6 alkyl group, or NMe₂; R₄ is a C1-C6 alkyl group; m=2-4; u=0-2; v=0-1; x=1-3; y=0-2; z=0-1; u+x+y+z=4 or 2v+x+y+z=4; and u, v, or z≧1, and more particularly Ti(iPr—N—C(Me)—N-iPr)₁(OiPr)₃, Ti(iPr—N—(CH₂)₂—N-iPr)₁(OiPr)₂, Ti(iPr—N—C(H)—N-iPr)₂(OiPr)₂, Ti(iPr—N—C(Me)—N-iPr)(OiPr)₂(NMe₂), Ti(iPr—N—C(Me)—N-iPr)(OiPr)₂(O₂CMe), Ti(Et-N—C(Me)—N-Et)(OiPr)₂(O₂CMe), Ti(iPr—N—(CH₂)₂—N-iPr)(OiPr)(O₂CMe), Ti(OiPr)₂(O₂CMe)₂, or Ti(OiPr)₃(O₂CMe).

Upon obtaining a desired film thickness, the film may be subject to further processing, such as thermal annealing, furnace-annealing, rapid thermal annealing, UV or e-beam curing, and/or plasma gas exposure. Those skilled in the art recognize the systems and methods utilized to perform these additional processing steps. For example, the silicon-containing film may be exposed to a temperature ranging from approximately 200° C. to approximately 1000° C. for a time ranging from approximately 0.1 second to approximately 7200 seconds under an inert atmosphere, a H-containing atmosphere, a N-containing atmosphere, an O-containing atmosphere, or combinations thereof. Most preferably, the temperature is 400° C. for 3600 seconds under a H-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, is expected to effectively reduce any carbon and nitrogen contamination of the alkali metal-containing film. This in turn is expected to improve the resistivity of the film.

### EXAMPLES

The following non-limiting examples are provided to further illustrate embodiments of the invention. However, the examples are not intended to be all inclusive and are not intended to limit the scope of the inventions described herein.

### Example 1

### Synthesis of bis(diisobutylamino)silane

A 2.5M hexanes solution of n-butyl lithium (112.4 mL, 0.281 mol) was added dropwise to a −40° C. solution of diisobutylamine (49.1 mL, 0.281 mol) in pentane (200 mL). After addition is complete, suspension is warmed to ambient temperature while stirring for 2 hours. A solution of diiodosilane (30.0 g, 0.106 mol) in pentane (100 mL) was then transferred slowly via cannula to the cooled, −40° C. solution of lithium amide (above) resulting in the immediate formation of a colorless precipitate. The suspension was warmed slowly to ambient temperature while stirring overnight. The following day, stirring is stopped to allow precipitate to settle and supernatent solution filtered over a medium pore glass frit with a bed of Celite. The precipitate was then extracted with 2×70 mL pentane with extracts combined and filtered with above to yield a hazy, pale yellow solution. Solvents (pentane and hexanes) are distilled off at 70° C. and atmospheric pressure. A fresh receiving flask is added and desired product is distilled at 80° C.-60 mTorr as a colorless liquid (29 g, 72%). bp 302° C.; 1H NMR (C6D6, 400 MHz) δ(ppm)=4.82 (s, 2H, Si—H), 2.65 (d, 8H, N—CH2), 1.80 (mult., 4H, CH2-CH), 0.89 (d, 24H, CH—CH3).

### Example 2

### Synthesis of bis(di(n-butyl)amino)silane

A 2.5M hexanes solution of n-butyl lithium (56.4 mL, 0.141 mol) was added dropwise to a 0° C. solution of di-(n-butyl)amine (23.6 mL, 0.140 mol) in pentane (200 mL). After addition is complete, suspension is warmed to ambient temperature while stirring for 3 hours. The solution of lithium amide is then transferred slowly via cannula to a 0° C. solution of diiodosilane (20.0 g, 0.070 mol) in pentane (200 mL) resulting in the immediate formation of a colorless precipitate. The suspension was warmed slowly to ambient temperature while stirring overnight. The following day, stirring is stopped to allow precipitate to settle and supernatent solution filtered over a medium pore glass frit with a bed of Celite. The precipitate was then extracted with 2×50 mL pentane with extracts combined and filtered with above to yield a hazy, pale yellow solution. Solvents (pentane and hexanes) are distilled off at 70° C. and atmospheric pressure. A fresh receiving flask is added and desired product is distilled at 85-90° C.60-70 mTorr as a colorless liquid (8.6 g, 43%). bp 320° C.; 1H NMR (C6D6, 400 MHz) δ(ppm)=4.84 (s, 2H, Si—H), 2.88 (t, 8H, N—CH2), 1.47 (m, 8H, CH2-CH2), 1.30 (m. 8H, CH2-CH3), 0.92 (t, 12H, CH2-CH3).

### Example 3

### Synthesis of bis(N-tert(butyl)isopropylamino)silane

A 2.5M hexanes solution of n-butyl lithium (101.0 mL, 0.253 mol) was added dropwise to a −40° C. solution of N-tert-butyl-isopropylamine (40.0 mL, 0.252 mol) in pentane (200 mL). After addition is complete, the suspension is warmed to ambient temperature while stirring for 2 hours. A solution of diiodosilane (35.0 g, 0.123 mol) in pentane (100 mL) was then transferred slowly via cannula to the cooled, −40° C. solution of lithium amide (above) resulting in the immediate formation of a colorless precipitate. The suspension was warmed slowly to ambient temperature while stirring overnight. The following day, stirring is stopped to allow precipitate to settle and supernatent solution filtered over a medium pore glass frit with a bed of Celite. The precipitate was then extracted with 2×70 mL pentane with extracts combined and filtered with above to yield a hazy, pale yellow solution. Solvents (pentane and hexanes) are distilled off at 70° C. and atmospheric pressure. A fresh receiving flask is added and desired product is distilled at 68-70° C.-100 mTorr as a colorless, semi-crystalline solid (10.8 g, 34%). mp 28° C.; by 298° C.; 1H NMR (C6D6, 400 MHz) δ(ppm)=5.12 (s, 2H, Si—H), 3.24 (m, 2H, N—CH), 1.29 (d, 12H, CH—CH3), 1.26 (s, 18H, C—CH3).

### Example 4

### Synthesis of bis(diisopropylamino)silane

A similar process was used to produce bis(diisopropylamino)silane as a colorless liquid.

(11.3 g, 47%). mp−12° C.; by 281° C.; 1H NMR (C6D6, 400 MHz) δ(ppm)=4.91 (s, 2H, Si—H), 3.26 (sept., 4H, N—CH), 1.14 (d, 24H, CH—CH3).

### Example 5

ALD depositions were performed using tetrakis(diethylamino)hafnium (TDEAH), H₂O and the silicon containing compounds listed in the following table.

| | 1:1 | | 2:1 | | 3:1 | | 4:1 | | |
|---|---|---|---|---|---|---|---|---|---|
| | Hf/Si | | Hf/Si | | Hf/Si | | Hf/Si | | Tunability |
| Molecule | A | B | A | B | A | B | A | B | (%) |
| N(SiH3)3 | 0 | | | | | | | | 0 |
| SiH3(NiPr2) | 0 | | | | | | | | 0 |
| Si(N═C═O)4 | 40 | | 33 | | | | | | 33-40 |
| H2Si(NEt2)2 | 56 | 45 | 55 | 39 | | | | | 39-56 |
| H2Si(NiPr2)2 | 53 | 57 | 29 | 42 | 32 | 21 | | | 21-57 |
| H2Si(NiBu2)2 | 19 | 29 | 13 | 23 | 9 | 16 | 7 | 15 | 7-50 |
| H2Si(NnBu2)2 | 26 | 37 | 24 | 34 | 18 | 28 | 22 | 32 | 18-44 |
| H2Si(NtBuiPr)2 | 35 | 45 | 22 | 32 | 15 | 23 | 16 | 26 | 15-40 |

Silicon content was determined by X-ray photoelectron spectroscopy (XPS) at a 30 sec sputter (column A) and from a surface measurement (column B). The tunability results provided do not include silicon atomic % from ratios not listed. The actual tunability results may be broader than indicated. Furthermore, if higher silicon concentrations are desired, the Hf:Si ratio may be inverted to introduce more silicon containing precursor than hafnium containing precursor (i.e., 4:1 Si/Hf).

As can be seen, bis(diethylamino)silane and bis(diisopropylamino)silane may be selected to deposit hafnium silicate films having higher silicon content. Higher silicon content may be beneficial for interlayer insulating films or spacer films.

As can also be seen, bis(diisobutylamino)silane and bis(isopropyltbutylamino)silane may be selected to deposit hafnium silicate films having lower silicon content. Lower silicon content may be beneficial for gate dielectrics.

By selecting the appropriate silicon containing precursor, a hafnium silicate film having a desired silicon content may be produced. The silicon content may further be adjusted by adjusting the ratio of the hafnium containing precursor to the silicon containing precursor.

### Example 6

ALD depositions were performed using TDEAH, H₂O and bis(diisobutylamino)silane. The reactor pressure was approximately 2.3 Torr. The reactor temperature was between approximately 250° C. and approximately 300° C. TDEAH was introduced into the reactor for approximately 15 seconds, followed by an approximately 10 second nitrogen purge. H₂O was introduced into the reactor for approximately 1 second followed by an approximately 10 second nitrogen purge. Bis(diisobutylamino)silane was introduced for 5, 10, or 20 seconds followed by a 10 second nitrogen purge. H₂O was introduced into the reactor for 1.5 seconds followed by an approximately 10 second nitrogen purge. As shown in FIG, the deposition rate and refractive index remained steady with increasing bis(diisobutylamino)silane pulse time. A slightly higher growth rate, slightly lower silicon content, and slightly higher impurity level was observed at 300° C. as compared to 250° C. The carbon and nitrogen incorporation in the hafnium silicate film were below the ˜1 atomic % detection limit. The higher level of impurities at 300° C. may result from decomposition of TDEAH.

### Example 7

ALD depositions were performed using TDEAH, H₂O and bis(di-n-butylamino)silane. The reactor pressure was approximately 0.2 Torr. The reactor temperature was approximately 300° C. TDEAH was introduced into the reactor for approximately 15 seconds, followed by an approximately 10 second nitrogen purge. H₂O was introduced into the reactor for approximately 1 second followed by an approximately 10 second nitrogen purge. Bis(di-n-butylamino)silane was introduced for 10 seconds followed by a 10 second nitrogen purge. H₂O was introduced into the reactor for 1.5 seconds followed by an approximately 10 second nitrogen purge. A hafnium silicate film having approximately 18 atomic silicon was produced from a 3:1 ratio of hafnium containing precursor: silicon containing precursor.

### Example 8

ALD depositions were performed using TDEAH, H₂O and bis(di-isopropylamino)silane. A hafnium silicate film having approximately 18 atomic silicon was produced from a 3:1 ratio of hafnium containing precursor: silicon containing precursor. The concentration of silicon in the hafnium silicate film varies broadly using bis(diisopropylamino)silane, providing an excellent precursor for tenability as compared to the other aminosilanes.

### Comparative Example 1

ALD depositions were performed at 250° C. using TDEAH, H₂O and Si(N═C═O)₄. A hafnium silicate film was produced having approximately 33 atomic % silicon from a 1:1 Hf containing precursor:Si containing precursor ratio to approximately 40 atomic % silicon from a 2:1 Hf containing precursor:Si containing precursor ratio, both at the 30 second XPS sputter measurement. The hafnium silicate films also contained approximately 3 atomic % to approximately 4 atomic % nitrogen.

### Comparative Example 2

ALD depositions were performed at 300° C. using TDEAH, H₂O and N(SiH₃)₃. The films deposited had a refractive index close to that of pure HfO₂. The deposition rate was also close to that of TDEAH and H₂O. The XPS results indicated no Si+4 incorporation, only Si2p incorporation from the substrate.

### Comparative Example 3

ALD depositions were performed at 300° C. using TDEAH, H₂O and SiH₃(NiPr₂). The films deposited had a refractive index close to that of pure HfO₂. The deposition rate was also close to that of TDEAH and H₂O. The XPS results indicated no Si+4 incorporation, only Si2p incorporation from the substrate.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

What is claimed is:

1. An atomic layer deposition (ALD) method to provide a hafnium silicate film having a desired silicon concentration, the method comprising:
a) introducing a hafnium containing precursor into a chamber containing one or more substrates;
b) adsorbing at least part of the hafnium containing precursor on the one or more substrates to produce an adsorbed hafnium containing layer;
c) selecting a silicon containing precursor to provide a desired concentration of silicon in the hafnium silicate film, the silicon containing precursor having either formula (a) HₓSi(NR¹R²)₄₋ₓ, wherein x is 1 or 2 and R¹ and R² are independently selected from the group consisting of H, Me, Et, nPr, iPr, nBu, iBu, tBu, sBu, and tAm; or formula (b) HₓSi(morpholino)₄₋ₓ, wherein x is 2 or 3; and
d) introducing the selected silicon containing precursor into the chamber to react with the adsorbed hafnium containing layer to provide the hafnium silicate film having the desired silicon concentration.

2. The ALD method of claim 1, further comprising introducing a reactant into the chamber after the chemisorption of at least part of the hafnium containing precursor and/or after introducing the selected silicon containing precursor.

3. The ALD method of claim 2, wherein the reactant is H₂O.

4. The ALD method of claim 1, wherein the silicon containing precursor selected is bis(diisobutylamino)silane and the desired silicon concentration is between approximately 7 atomic % and approximately 50 atomic %.

5. The ALD method of claim 1, wherein the silicon containing precursor selected is bis(di-n-butylamino)silane and the desired silicon concentration is between approximately 18 atomic % and approximately 44 atomic %.

6. The ALD method of claim 1, wherein the silicon containing precursor selected is bis(diethylamino)silane and the desired silicon concentration is between approximately 39 atomic % and approximately 56 atomic %.

7. The ALD method of claim 1, further comprising increasing a ratio of hafnium containing precursor to silicon containing precursor to further decrease the silicon concentration.

8. The ALD method of claim 1, further comprising annealing the hafnium silicate film.

9. A method of decreasing a silicon concentration in a hafnium silicate film by increasing a carbon chain length in a silicon containing precursor having the formula HₓSi(NR¹R²)₄₋ₓ, wherein x is 1 or 2 and R¹ and R² are independently selected from the group consisting of H, Me, Et, nPr, iPr, nBu, iBu, tBu, sBu, and tAm.

10. The method of claim 9, wherein the silicon containing precursor is bis(diisobutylamino)silane and the silicon concentration is between approximately 7 atomic % and approximately 50 atomic %.

11. The method of claim 9, wherein the silicon containing precursor is bis(di-n-butylamino)silane and the silicon concentration is between approximately 18 atomic % and approximately 44 atomic %.

12. The method of claim 9, wherein the silicon containing precursor is bis(diethylamino)silane and the silicon concentration is between approximately 39 atomic % and approximately 56 atomic %.
